(19) United States
(12) Patent Application Publication
(10) Pub. No.: US 2026/0228382 A1
(43) Pub. Date: Aug. 6, 2026

(54) SIMULATING ULTRASOUND BEAM PROFILES

(71) Applicant: Zeta Surgical Inc., Boston, MA (US)

(72) Inventors: Zheng Jiang, London (GB); Jacqueline Taylor Li, Boston, MA (US); Raahil Mohammed Sha, Allen, TX (US); Jose Maria Amich Manero, Cambridge, MA (US); James J. Choi, London (GB)

(21) Appl. No.: 19/042,175

(22) Filed: Jan. 31, 2025

(51) Int. Cl. G06F 30/20

(52) U.S. Cl. CPC G06F 30/20

(57) ABSTRACT

Systems and methods for simulating ultrasound beam profiles are disclosed. A system can identify a plurality of virtual transducers for a simulation of an ultrasound procedure and select a plurality of subsets of the plurality of virtual transducers. The system can execute a plurality of simulations for the ultrasound procedure, where each of the plurality of simulations corresponds respectively to a respective subset of the plurality of subsets. The system can generate simulation results for the simulation of the ultrasound procedure by combining respective results of each of the plurality of simulations.

### CROSS-REFERENCE TO RELATED APPLICATIONS

This application claims the benefit of U.S. Provisional Application No. 63/627,480 filed Jan. 31, 2024, which is expressly incorporated by reference herein in its entirety for all purposes.

### BACKGROUND

### Field

The present application relates generally to the field of simulating ultrasound beam profiles.

### Description of Related Art

Ultrasound is a non-invasive modality that can be used for therapy, diagnosis, and monitoring procedures. The performance of each technique is sensitive to the kind of ultrasound beam applied onto the tissue and/or particles in the region; and/or the quality of the ultrasound received from the tissue and/or particles in the region. While simulations can aid in the prediction and correction of ultrasound that is emitted and/or received, they can often require immense computational power, memory, and time, making them cumbersome or impractical to use.

### SUMMARY

The systems and methods of this technical solution address the technical challenges encountered when simulating ultrasound propagation from and to transducers.

At least one aspect of the present disclosure is directed to a method. The method may be performed, for example, by one or more processors coupled to non-transitory memory. The method includes identifying a plurality of virtual transducers for a simulation of an ultrasound procedure. The method includes selecting a plurality of subsets of the plurality of virtual transducers. The method includes executing a plurality of simulations for the ultrasound procedure. Each of the plurality of simulations can correspond respectively to a respective subset of the plurality of subsets. The method includes generating simulation results for the simulation of the ultrasound procedure by combining respective results of each of the plurality of simulations.

In some implementations, the method includes selecting the plurality of subsets such that at least two of the plurality of subsets are overlapping with one another. In some implementations, the plurality of subsets each share a simulation volume. In some implementations, executing the plurality of simulations comprises executing, by the one or more processors, for each of the plurality of simulations, a time-domain acoustic simulation of the respective subset or a frequency-domain acoustic simulation of the respective subset. In some implementations, the method includes identifying one or more parameters of the simulation of the ultrasound procedure. In some implementations, the method includes executing the plurality of simulations according to the one or more parameters.

In some implementations, the method includes generating respective parameters for each of the plurality of simulations based on the one or more parameters. In some implementations, the method includes executing each of the plurality of simulations according to the respective parameters of the simulation. In some implementations, the one or more parameters comprise one or more of a number of dimensions for the simulation, a medium type for the simulation, respective positions of each of the plurality of virtual transducers, and parameters for operating the plurality of virtual transducers. In some implementations, selecting the plurality of subsets is further based on a target region defined in the simulation of the ultrasound procedure.

In some implementations, the simulation results for the simulation of the ultrasound procedure comprise a vector field of forces generated by the plurality of virtual transducers. In some implementations, the method includes presenting the simulation results of the ultrasound procedure at a display device. In some implementations, the ultrasound procedure is a transcranial ultrasound procedure, and the plurality of virtual transducers for the simulation are arranged in a hemispherical configuration. In some implementations, executing the plurality of simulations comprises independently executing each simulation of the plurality of simulations prior to combining the respective results of each simulation of the plurality of simulations.

At least one other aspect of the present disclosure is directed to a system. The system can include one or more processors coupled to non-transitory memory. The system can identify a plurality of virtual transducers for a simulation of an ultrasound procedure. The system can select a plurality of subsets of the plurality of virtual transducers. The system can execute a plurality of simulations for the ultrasound procedure. Each of the plurality of simulations can correspond respectively to a respective subset of the plurality of subsets. The system can generate simulation results for the simulation of the ultrasound procedure by combining respective results of each of the plurality of simulations.

In some implementations, the system can select the plurality of subsets such that at least two of the plurality of subsets are overlapping with one another. In some implementations, the plurality of subsets each share a simulation volume. In some implementations, the system can execute the plurality of simulations by executing, for each of the plurality of simulations, a time-domain acoustic simulation of the respective subset or a frequency-domain acoustic simulation of the respective subset. In some implementations, the system can identify one or more parameters of the simulation of the ultrasound procedure. In some implementations, the system can execute the plurality of simulations according to the one or more parameters.

In some implementations, the system can generate respective parameters for each of the plurality of simulations based on the one or more parameters. In some implementations, the system can execute, each of the plurality of simulations according to the respective parameters of the simulation. In some implementations, the one or more parameters comprise a number of dimensions, a medium type for the ultrasound procedure, respective positions of each of the plurality of virtual transducers, and parameters for operating the plurality of virtual transducers. In some implementations, the system can select the plurality of subsets further based on a target region defined in the simulation of the ultrasound procedure.

In some implementations, the simulation results for the simulation of the ultrasound procedure comprise a vector field of forces generated by the plurality of virtual transducers. In some implementations, the system can present the simulation results of the ultrasound procedure at a display device. In some implementations, the ultrasound procedure is a transcranial ultrasound procedure, and the plurality of virtual transducers for the simulation are arranged in a hemispherical configuration.

These and other aspects and implementations are discussed in detail below. The foregoing information and the following detailed description include illustrative examples of various aspects and implementations and provide an overview or framework for understanding the nature and character of the claimed aspects and implementations. The drawings provide illustration and a further understanding of the various aspects and implementations and are incorporated in and constitute a part of this specification. Aspects may be combined, and it will be readily appreciated that features described in the context of one aspect of the present disclosure may be combined with other aspects. Aspects may be implemented in any convenient form. In a non-limiting example, by appropriate computer programs, which may be carried on appropriate carrier media (computer readable media), which may be tangible carrier media (e.g., disks) or intangible carrier media (e.g. communications signals). Aspects may also be implemented using suitable apparatus, which may take the form of programmable computers running computer programs arranged to implement the aspect. As used in the specification and in the claims, the singular form of “a,” “an,” and “the” include plural referents unless the context clearly dictates otherwise.

### BRIEF DESCRIPTION OF THE DRAWINGS

FIG. 1 is a block diagram of an example system for simulating ultrasound beam profiles, in accordance with one or more implementations;

FIG. 2 is a front-view diagram of an example operation of transcranial ultrasound device, in accordance with one or more implementations;

FIG. 3A is a top view showing groups of virtual transducers for a simulation of an ultrasound procedure generated according to the techniques described herein, in accordance with one or more implementations;

FIG. 3B is a side view showing individual virtual transducers overlapping in a region of interest, in accordance with one or more implementations;

FIG. 4 is a flowchart of an example method for simulating ultrasound beam profiles, in accordance with one or more implementations;

FIG. 5 is a block diagram of an example computing system suitable for use in the various arrangements described herein, in accordance with one or more example implementations;

FIGS. 6A, 6B, and 6C provide diagrams showing how transducers of a multi-transducer device can be grouped for the simulation techniques described herein; and

FIGS. 7A and 7B provide diagrams showing how a single transducer can be sub-divided and simulated according to the techniques described herein.

### DETAILED DESCRIPTION OF SOME EMBODIMENTS

Non-invasive transcranial ultrasound procedures are conducted to provide rapid, real-time measurements of fluid flow in the brain. However, because transcranial ultrasound may induce a variety of effects on brain tissue, including neuromodulation, heating, and ablation, simulation can be used to predict how ultrasound waves will interact with brain tissue. Transcranial ultrasound procedures can be used to increase the permeability of target regions of the blood brain barrier, enabling targeted provisioning of drugs and/or microbubbles within the brain non-invasively. Conventional techniques for simulating systems with multiple transducers require simulating complex systems with several interactive beams. Transcranial ultrasound devices may include tens of transducers to simulate, thereby requiring significant computational resources to execute due to the exponentially increasing number of interactions between beams that result from each additional transducer. This increased computational complexity makes performing such simulations impracticable using conventional computing devices due to their inherent complexity.

Ultrasound devices for procedures may include a large number of individual transducers, which are impracticable to simulate as a whole due to the memory and number of calculations required to accurately measure the interactions between multiple propagating waves. The systems and methods described herein address these and other issues by grouping individual transducers of the ultrasound devices together and iteratively simulating the smaller groups of transistors. The results of these separate simulations are then combined to form composite simulation data, which may be used to evaluate the effects of the ultrasound process on tissues such as the brain. The techniques described herein therefore provide a technical improvement to ultrasound simulation systems by reducing the overall memory and computational complexity required to simulate complex ultrasound systems with many transducers.

The techniques described herein improve upon conventional simulation techniques by automatically dividing large numbers of transducers for an ultrasound simulation into groups of transducers. Each group of transducers may be selected, in some implementations, according to the computational capabilities (e.g., available memory, processing resources, or specialized hardware, etc.) of the computing system performing the simulation. Each group of transducers may then be individually simulated to generate a set of simulation results. The results of each simulation can then be combined to produce sets of simulation results for the ultrasounds simulation. Executing separate simulations for each group of virtual transducers, and subsequently combining results of each separate simulation, reduces the overall computational complexity and requirements of simulating ultrasound procedures, thereby improving conventional simulation systems. In some implementations, simulations of single transducers can be automatically divided into regions, which are subsequently simulated and combined according to the techniques described herein. The systems and methods described herein therefore provide a technical improvement to the field of acoustic wave simulation.

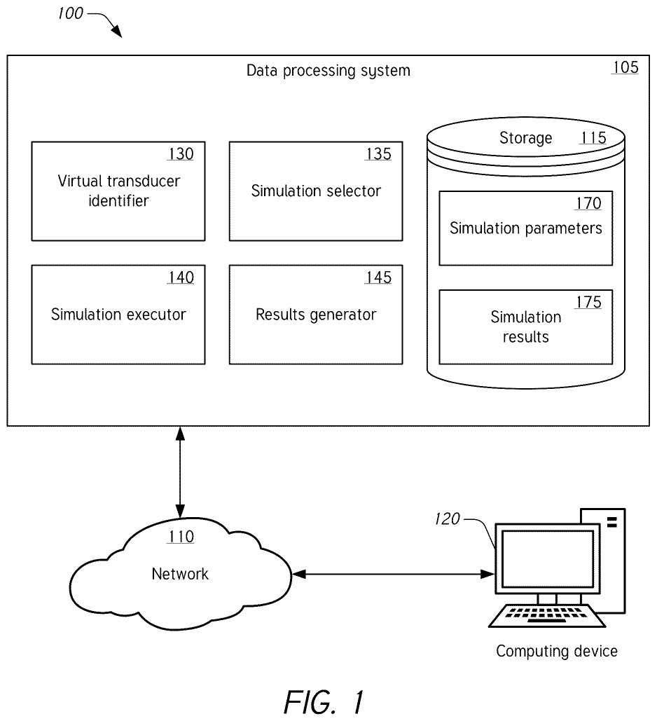

Referring to FIG. 1, illustrated is a block diagram of an example system for simulating ultrasound beam profiles, in accordance with one or more implementations. The system 100 can include at least one data processing system 105 (e.g., a simulator system 105). In some implementations, the system 100 can include at least one network 110 and at least one computing device 120. The data processing system 105 can include at least one virtual transducer identifier 130, at least one simulation selector 135, at least one simulation executor 140, at least one results generator 145, and at least one storage 115. The storage 115 can include one or more simulation parameter(s) 170 and one or more simulation result(s) 175.

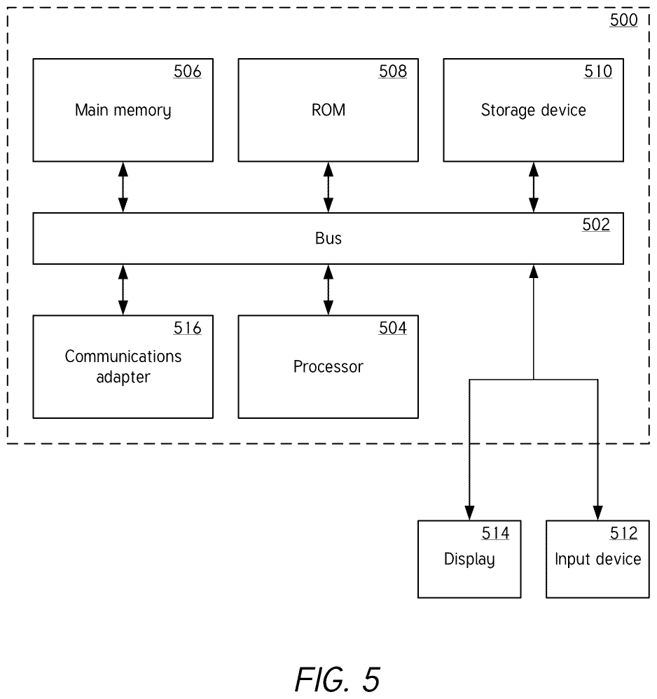

Each of the components (e.g., the data processing system 105, the network 110, the storage 115, the computing device 120, the virtual transducer identifier 130, the simulation selector 135, the simulation executor 140, the results generator 145, etc.) of the system 100 can be implemented using the hardware components or a combination of software with the hardware components of a computing system (e.g., computing system 500 of FIG. 5, etc.). Each of the components of the data processing system 105 can perform the functionalities detailed herein. In some implementations, one or more of the implemented by the data processing system 105, as described herein, may be additionally or alternatively performed by the computing device 120, or vice versa.

The data processing system 105 can include at least one processor and a memory, e.g., a processing circuit. The memory can store processor-executable instructions that, when executed by processor, cause the processor to perform one or more of the operations described herein. The processor can include a microprocessor, an application-specific integrated circuit (ASIC), a field-programmable gate array (FPGA), a graphics processing unit (GPU), a tensor processing unit (TPU), etc., or combinations thereof. The memory can include, but is not limited to, electronic, optical, magnetic, or any other storage or transmission device capable of providing the processor with program instructions. The memory can further include a floppy disk, CD-ROM, DVD, magnetic disk, memory chip, ASIC, FPGA, read-only memory (ROM), random-access memory (RAM), electrically erasable programmable ROM (EEPROM), erasable programmable ROM (EPROM), flash memory, optical media, or any other suitable memory from which the processor can read instructions. The instructions can include code from any suitable computer programming language. The data processing system 105 can include one or more computing devices or servers that can perform various functions as described herein. The data processing system 105 can include any or all of the components and perform any or all of the functions of the computer system 500 described herein in connection FIG. 5.

The network 110 can include computer networks such as the Internet, local, wide, metro or other area networks, intranets, satellite networks, other computer networks, such as mobile phone (voice or data) communication networks, or combinations thereof. The data processing system 105 of the system 100 can communicate via the network 110 with one or more computing devices, such as the computing device 120. The network 110 may be any form of computer network that can relay information between the data processing system 105, the computing device 120, and the storage 115, among others. In some implementations, the network 110 may include the Internet and/or other types of data networks, such as a local area network (LAN), a wide area network (WAN), a cellular network, a satellite network, or other types of data networks. The network 110 may also include any number of computing devices (e.g., computers, servers, routers, network switches, etc.) that are configured to receive or transmit data within the network 110.

The network 110 may further include any number of hardwired or wireless connections. Any or all of the computing devices described herein (e.g., the data processing system 105, the computing device 120, the computer system 500, etc.) may communicate wirelessly (e.g., via Wi-Fi, cellular communication, radio, etc.) with a transceiver that is hardwired (e.g., via a fiber optic cable, a CAT5 cable, etc.) to other computing devices in the network 110. Any or all of the computing devices described herein (e.g., the data processing system 105, the computing device 120, the computer system 500, etc.) may also communicate wirelessly with the computing devices of the network 110 via a proxy device (e.g., a router, network switch, or gateway).

The computing device 120 can include at least one processor and a memory (e.g., a processing circuit). The memory can store processor-executable instructions that, when executed by the processor, cause the processor to perform one or more of the operations described herein. The processor can include a microprocessor, an ASIC, an FPGA, a GPU, a TPU, etc., or combinations thereof. The memory can include, but is not limited to, electronic, optical, magnetic, or any other storage or transmission device capable of providing the processor with program instructions. The memory can further include a floppy disk, CD-ROM, DVD, magnetic disk, memory chip, ASIC, FPGA, ROM, RAM, EEPROM, EPROM, flash memory, optical media, or any other suitable memory from which the processor can read instructions. The instructions can include code from any suitable computer programming language.

The computing device 120 can be a personal computer, a laptop computer, a television device, a smart phone device, a mobile device, or another type of computing device. The computing device 120 can be implemented using hardware or a combination of software and hardware. The computing device 120 can include a display or display portion. The display can include a display portion of a television, a display portion of a computing device, or another type of interactive display (e.g., a touchscreen, etc.). The computing device 120 may include one or more I/O devices (e.g., a mouse, a keyboard, digital keypad, buttons, trackpads, touch sensor of the touchscreen, etc.). The display can include a touch screen displaying an application, such as a web browser application or a native application, which may be used to access the functionality of the data processing system 105 to perform any of the techniques described herein.

In some implementations, the computing device 120 can be used to transmit requests to perform one or more simulations of ultrasound procedures to the data processing system 105 or otherwise communicate with the data processing system 105 to initiate simulations of ultrasound procedures. To do so, the computing device 120 may transmit one or more simulation parameters 170 to the data processing system 105. In some implementations, the computing device 120 may identify one or more simulation parameters 170 previously stored in the storage 115 to use to implement one or more simulations of an ultrasound process. Simulations of ultrasound processes can include simulations of ultrasound therapy (e.g., ultrasound travelling from one or more transducers to a target region, etc.), ultrasound monitoring (e.g., ultrasound travelling from one or more target regions to one or more transducers, etc.), and ultrasound imaging (e.g., ultrasound travelling from one or more transducers to a target region, and ultrasound travelling from the target region to the one or more transducers, etc.). The computing device 120 can display, or otherwise access, the simulation results 175 of any of the simulations described herein. For example, the computing device can access, present for display, or store any simulation results of any set or subset of virtual transducers, or combined simulation results generated by the results generator 145, as described in further detail herein. Although the data processing system 105 and the computing device 120 are shown as having a client-server relationship, it should be understood that in some implementations, the data processing system 105 may be a standalone computing device or computing system that includes a display device and I/O devices. In such implementations, the data processing system 105 may implement any of the functionalities of the computing device 120 described herein, and may not necessarily transmit, or retrieve/receive, any data via the network 110. In some implementations, the network 110 and the computing device 120 may not be included in the system 100.

The storage 115 can be a database, or another type of computer memory storage, configured to store and/or maintain any of the information described herein. The storage 115 can maintain one or more data structures, which can contain, index, or otherwise store each of the values, pluralities, sets, variables, vectors, thresholds, or other data described herein. The storage 115 can be accessed using one or more memory addresses, index values, or identifiers of any item, structure, or region maintained in the storage 115. The storage 115 can be accessed by the components of the data processing system 105, or any other computing device described herein, via a network or another type of communications interface. In some implementations, the storage 115 can be internal to the data processing system 105. In some implementations, the storage 115 can exist external to the data processing system 105 and can be accessed via a network (e.g., the network 110) or another type of communications interface. In some implementations, the storage 115 can be distributed across many different computer systems or storage elements. The data processing system 105 can store, in one or more regions of the memory of the data processing system 105, or in the storage 115, the results of any or all computations, determinations, selections, identifications, generations, constructions, or calculations in one or more data structures indexed or identified with appropriate values. Any or all values stored in the storage 115 can be accessed by any computing device described herein, such as the data processing system 105, to perform any of the functionalities or functions described herein.

The storage 115 is shown as storing one or more simulation parameters 170, for example, in one or more data structures. The simulation parameters 170 may include any initial conditions or input parameters for performing an ultrasound simulation (e.g., a k-Wave simulation, etc.). The simulation parameters may include, but are not limited to, domain dimensions (e.g., a specification of a space to simulate), information describing the simulation medium (e.g., the medium through which the acoustic waves are to propagate in the simulation), time steps (e.g., the number of timesteps to simulate), and data describing one or more pressure sources to simulate (e.g., virtual transducers). The data describing the virtual transducers may include virtual locations of the transducers in the simulation domain, acoustic properties of the transducers (e.g., size, power, frequency, etc.). In some implementations, the simulation parameters may include acoustic property maps of a subject for which the ultrasound procedure is to be performed. The acoustic property maps may be derived from computed tomography (CT) or magnetic resonance imaging (MRI) images and may include acoustic properties of various tissues or structures of the subject. The simulation parameters 170 may include parameters generated for sets of simulations created by the simulation selector 135, as described in further detail herein.

The storage 115 is shown as storing one or more simulation results 175, for example, in one or more data structures. The simulation results 175 for a simulation may include pressure, velocity, or force fields describing the forces experienced at one or more locations (e.g., voxels) within the simulated volume of the simulation. The simulation results 175 can include beam information of each simulated virtual transducer, such as each virtual transducer's focusing ability and the shape of its beam pattern. The simulation results 175 may include results of sets of simulations (sometimes referred to herein as “sub-simulations”) generated by the simulation selector 135 and executed by the simulation executor 140. The simulation results 175 can include combined results of multiple sub-simulations, as described herein. The simulation results 175 can be stored in association with identifiers of one or more subjects, virtual transducers, or requests to perform corresponding simulations. The simulation results 175 for a simulation can include one or more visualizations of acoustic wave propagation in the simulated volume, which can be generated by the results generator 145 or the computing device 120. The simulation results 175 can include any type of output of any simulation or sub-simulation described herein.

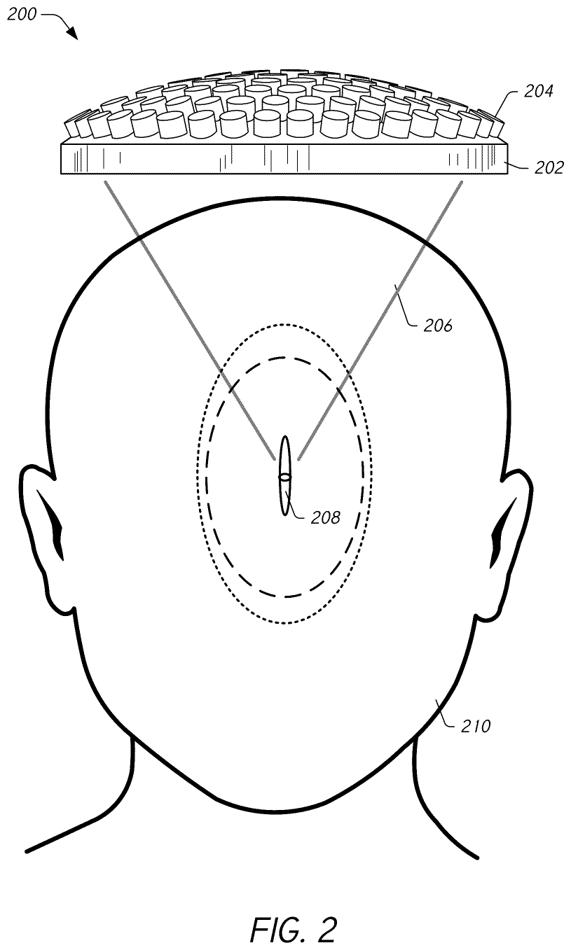

Prior to discussing the various implementations of techniques for simulating ultrasound beam profiles, a brief overview of an example ultrasound procedure that may be simulated is provided. Referring to FIG. 2, illustrated is a front-view diagram 200 of an example operation of transcranial ultrasound device 202, in accordance with one or more implementations. In this example, the transcranial ultrasound device 202 is an ultrasound transducer with an array of individual transducers 204. Each of the individual transducers 204 generates a respective ultrasound beam (e.g., propagating waves) by actuating at a predetermined frequency suitable for ultrasound. Constructive and destructive interference between the waves emitted by each individual transducer 204 creates a focused beam 206 that delivers an amount of energy to a target location 208 within a target medium (in this example, the head of a subject 210). Since transcranial ultrasound procedures can potentially cause harm if performed incorrectly, simulations of the ultrasound procedure can be performed to analyze how the ultrasound procedure is to affect the subject during an actual procedure. For example, simulations may be performed to achieve accurate focusing of ultrasound beam profiles given predetermined subject anatomy, and to determine parameters for controlling the individual transducers 204 of the ultrasound device 2020 to achieve desired power output at a target location. The techniques described herein enable improved performance and reduced computational requirements when simulating ultrasound devices having arbitrary numbers of individual transducers 204.

Referring back to FIG. 1, and to the functionality of the components of the data processing system 105, the virtual transducer identifier 130 can identify virtual transducers for a simulation of an ultrasound procedure. Prior to grouping the transducers to improve simulation performance, each of the transducers, and their corresponding properties (or related simulation properties) can be identified and stored for use by various components of the data processing system 105. For example, the virtual transducer identifier 130 can access information (e.g., a settings file, configuration data, etc.) relating to an ultrasound device (e.g., a virtual version of the ultrasound device 202 of FIG. 2) to be simulated. The virtual transducers (e.g., virtualized versions of the transducers 204) may be represented by data structures storing various properties of transducers of the ultrasound device, such as size, location, and beam properties (e.g., direction, actuation frequency, phase, etc), force, an identifier of the transducer, among other properties. The configuration may be retrieved or otherwise extracted from the simulation parameters 170 for a simulation of an ultrasound procedure, which may be provided via user input, via the network 110 from the computing device 120, or retrieved from a computing device via the network 110.

The virtual transducer identifier 130 may also extract additional simulation parameters 170 for the simulation of the ultrasound procedure, which may include information relating to domain dimensions of the simulation, simulation medium information (e.g., which may be derived at least in part from medical images of a subject), and a number and length of time steps to simulate, among others. Information relating to the virtual transducers may include information relating to a target location toward which the virtual beams of the virtual transducers are to be focused. In some implementations, the virtual transducer identifier 130 can identify the virtual transducers in response to a request from a computing device 120, or in response to user input via one or more I/O devices of the data processing system 105.

The simulation selector 135 can select multiple subsets (e.g., groups) of the virtual transducers to create multiple simulations. Conventional simulation techniques require all transducers to be simulated in a single simulation, which can exhaust computing resources or can otherwise by computationally impracticable to perform. To address at least these issues, the simulation selector 135 can generate groups of virtual transducers for simulation, for example, based on the location of the transducers. In some implementations, the simulation selector 135 can select groups of virtual transducers that are proximate to one another. Each group may include one or more transducers. In one implementation groups of virtual transducers may be selected by spatially dividing the transducers of the virtual ultrasound device among spaces in a virtual grid, such that each space in the grid includes a number of virtual transducers in a single group.

In some implementations, virtual transducers in each group may be selected based on processing capabilities of the data processing system 105. For example, the size of each group of virtual transducers (e.g., the number of virtual transducers in each group) may be selected based on an available computational memory or available computational resources of general-purpose processors and/or dedicated processing hardware (e.g., GPUs, TPUs, etc.) of the data processing system 105. The simulation selector 135 can select groups of virtual transducers such that at least two groups include the same transducer (e.g., at least two groups are overlapping with one another). Further, the simulation selector 135 can select the groups of virtual transducers such that every group shares at least one transducer (e.g., at least one transducer is included in every group as a common transducer).

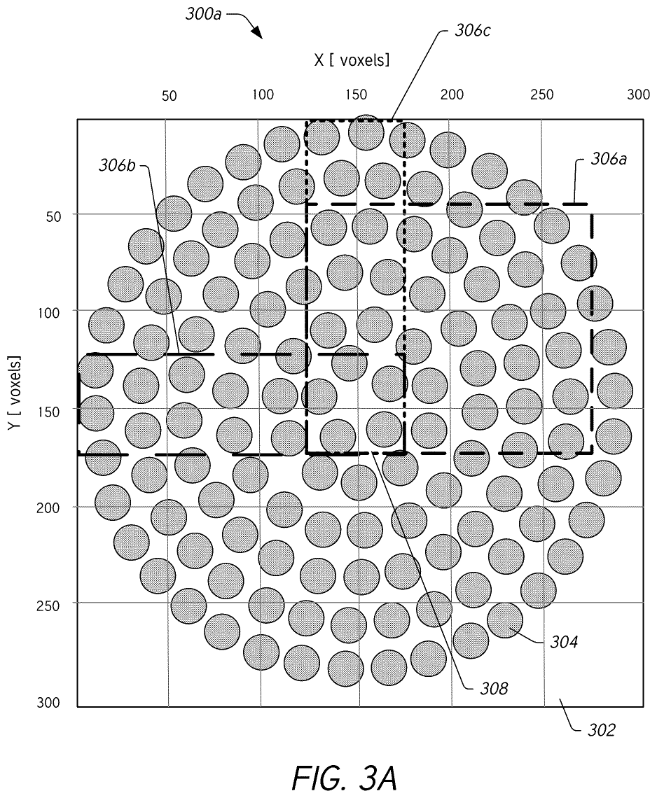

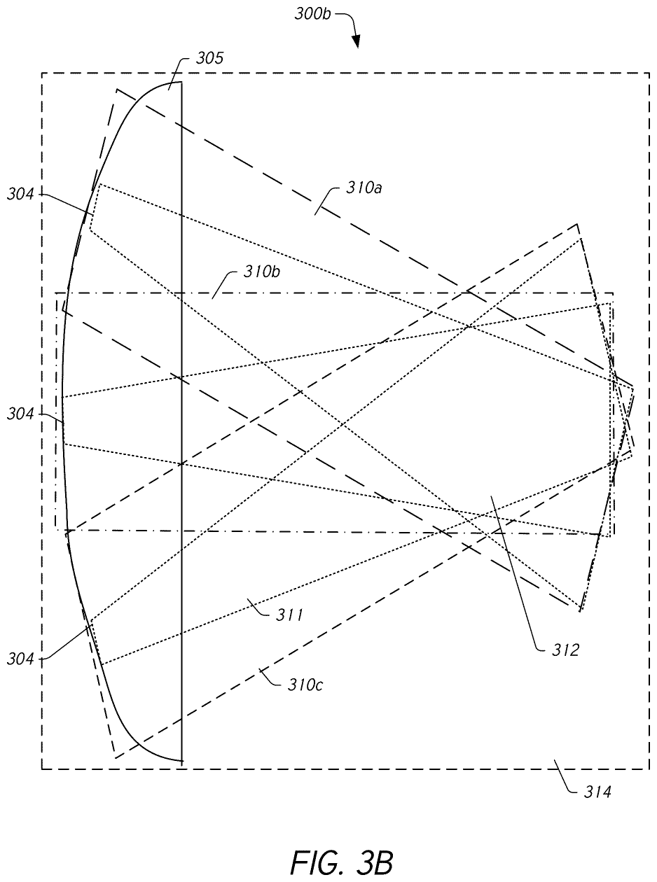

In some implementations, the subsets of virtual transducers can be selected by the simulation selector 135 based on a region of interest (e.g., a target location or target region within a subject on which the ultrasound is to be performed). In such implementations, the transducers can be selected such that the operating volume of each group (e.g., the volume through which ultrasound waves emitted by the group is to propagate) overlaps in the region of interest. An example representation of selection of groups of virtual transducers with overlapping operating volumes at a region of interest is shown in FIG. 3A.

Referring to FIG. 3A in the context of the components described in connection with FIG. 1, illustrated is a top view 300A showing groups of virtual transducers 304 within sub-volumes 306A, 306B, and 306C of a simulation domain 302 for a simulation of an ultrasound procedure generated according to the techniques described herein. The top view 300A depicts individual transducers 304 of an example ultrasound device, which may be similar to the ultrasound device 204 shown in FIG. 2. As shown, each of the groups within the sub-volumes 306A, 306B, and 306C include multiple transducers. In this example, virtual transducers on the boundary of a sub-volume can be included in the group of virtual transducers. As shown, sub-volumes 306A, 306B, and 306C can overlap with one another, and therefore some transducers may be included in multiple groups. Additionally, the sub-volumes 306A, 306B, and 306C overlap in the region 308, which may correspond to a region of interest to be simulated.

The simulation selector 135 can, in some implementations, select the groups of virtual transducers by first selecting the sub-volumes 306A, 306B, and 306C that overlap in the region of interest. In such implementations, the sub-volumes can be selected or generated by subdividing the simulation domain 302, such that each sub-volume includes a corresponding subset of the transducers 304. The sub-volumes can be selected to each include at least one transducer 304, and to include at least the region of interest 308.

The simulation selector 135 can select the sub-volumes based on one or more of the computational constraints (e.g., memory, estimated processing time, etc.) of the data processing system 105, and may optimize selection of the sub-volumes to minimize overlap in regions that are not the region of interest 308. The region of interest may be a volume within the subject for which the ultrasound procedure is to be performed and may not necessarily be proximate to or envelope any of the transducers 304. In some implementations, the sub-volumes can be selected such that each transducer 304 of the ultrasound device to be simulated is included in at least one sub-volume. In some implementations, the simulation selector 135 can select groups of virtual transducers 304 prior to selecting or determining sub-volumes. In such implementations, the simulation selector 135 can determine sub-volumes for each group of virtual transducers 304 such that each volume encompasses at least the region of interest 308. The sub-volumes determined by the simulation selector 135 can be smaller than the volume defined by the simulation domain 302.

In some implementations, the simulation selector 135 can determine an expected memory resource usage for performing a simulation according to one or more parameters of the simulation including at least a number of virtual transducers of a given sub-volume (e.g., based on a predefined or expected resource usage value corresponding to the number of virtual transducers of the given sub-volume), compare the expected memory resource usage with an available memory resource capacity of the computing device 120 and/or data processing system 105, and adjust the number of virtual transducers of the given sub-volume based on the comparison (e.g., adjust the number to be a maximum value of virtual transducers such that the expected memory resource usage is less than the available memory resource capacity and/or less than the available memory resource capacity by a buffer factor).

Although the x and y axes are shown in FIG. 3A, it should be understood that the simulation domain 302 can be a two-dimensional or a three-dimensional domain (e.g., including a z-axis). Moreover, the region of interest 308 is a three-dimensional region within the simulation domain 302 that can have any suitable shape. Likewise, the shape of any sub-volume of the simulation domain 302 determined by the simulation selector 135 can have any suitable shape or size, as long as the sub-volume encompasses at least the region of interest 308. Although only three groups 306A, 306B, and 306C of virtual transducers are shown in this example, in some implementations, the groups selected by the simulation selector 135 can each include just a single transducer. An example where each group includes a single transducer is shown in FIG. 3B.

Referring to FIG. 3B in the context of the components described in connection with FIG. 1, illustrated is a side view 300B showing individual virtual transducers 304 each having virtual beams 311 that overlap in a region of interest 312. The region of interest 312 may be similar to the region of interest 308 of FIG. 3A and can represent a region at which the beams 311 of the virtual transducers 304 are to converge during the simulation. The region of interest 312 may represent a location of a target region within the anatomy of a subject upon which the ultrasound procedure is to be performed.

In this example, respective sub-volumes 310A, 310B, and 310C are selected to encompass the each of the virtual transducers 304, the virtual beam of the virtual transducer 304, and the region of interest 312. Each of the sub-volumes 310A, 310B, and 310C of FIG. 3B may be similar to the volumes 306A, 306B, and 306C of FIG. 3A, except that, in some implementations, the sub-volume can be selected to include only a single virtual transducer 304. As described in further detail herein, each sub-volume can correspond to a volume that is to be simulated. In implementations where each sub-volume includes only a single transducer, the sub-volume may be selected such that it intersects with or includes a second transducer, but that second transducer is not simulated as part of the simulation of the sub-volume. Instead, the second transducer can be simulated separately by generating a corresponding sub-volume for that second transducer 304. Once selected by the simulation selector 135, the groups of virtual transducers (or single transducers), as well as their corresponding sub-volumes, can be simulated by the simulation executor 140.

Referring back to FIG. 1, the simulation executor 140 can execute the simulations (sometimes referred to herein as “sub-simulation(s)”) for the ultrasound procedure. To do so, the simulation executor 140 can generate sub-simulations for each group of virtual transducers selected by simulation selector 135. Each group of virtual transducers can correspond to a respective sub-volume of the simulation domain of the ultrasound simulation, as described herein. The simulation executor 140 can establish parameters for each sub-simulation of each group of virtual transducers. To do so, the simulation executor 140 can identify one or more simulation parameters 170 of the simulation of the ultrasound procedure and utilize the simulation parameters 170 to generate corresponding parameters for each sub-simulation. The simulation executor 140 can execute at least one first sub-simulation independently from at least one second sub-simulation, such as to perform the first sub-simulation using a first group of virtual transducers of the plurality of virtual transducers and not using any other virtual transducers outside of the first group, and to perform the second sub-simulation using a second group of virtual transducers of the plurality of virtual transducers and not using any other virtual transducers outside of the second group (where the first and second groups may have at least some common virtual transducers).

For example, the simulation executor 140 can be one or more of domain dimensions for the simulation, a medium type for the simulation, respective positions of each of the plurality of virtual transducers, and parameters for operating the plurality of virtual transducers. The parameters for each sub-simulation may include a medium type for the corresponding sub-volume, respective position(s) of each virtual transducer in the group corresponding to the sub-volume, initial conditions for the sub-simulation, and operating characteristics of the one or more virtual transducers included in the group. The simulation executor 140 can store the parameters for each sub-simulation as part of the simulation parameters 170, in some implementations.

Once the parameters for a sub-simulation are generated, the simulation executor 140 can execute the sub-simulation according to the parameters. The simulation may be any type of simulation that can be used to simulate ultrasound procedures, including transcranial ultrasound procedures. For example, the simulations can be a k-Wave simulation, a finite-difference time-domain (FDTD) simulation, a transcranial ultrasound simulation toolbox (TUSX) simulation, or a frequency-domain acoustic simulation of the respective subset among others. Executing the simulation may include iteratively solving one or more partial differential equations that model the behavior of acoustic waves in different mediums. To execute the simulations, the simulation executor 140 can allocate regions of memory or invoke additional computational resources (e.g., GPUs, TPUs, etc.) carry out the computations for each sub-simulation. When executing a sub-simulation, the simulation executor 140 can, in some implementations simulate only the transducers included in the group corresponding to the sub-simulation and only within the corresponding sub-volume, rather than performing a full-field simulation of the entire simulation domain (e.g., the simulation domain 302, the simulation domain 314, etc.). This can allow for scaling effects for resource usage for the sub-simulation, relating to factors such as the number of virtual transducers used for the sub-simulation, to be mitigated (e.g., in situations in which the computational resource usage for the sub-simulation increases nonlinearly with the number of virtual transducers used for the sub-simulation) as compared with a simulation of the entire simulation domain in a single simulation; as described above and further herein, the data processing system 105 can continue to achieve target accuracy or other quality performance metrics for the overall simulation results by combining the simulation results from the sub-simulations (e.g., target accuracy can be achieved while computational resource usage is reduced).

The output of each simulation executed by the simulation executor 140 can be stored as part of the simulation results 175. The results of each sub-simulation can include any simulation data that may be relevant to acoustic ultrasound procedures, including but not limited to acoustic pressure, particle velocity, and acoustic intensity at each point simulated within the sub-volume that was simulated. The simulation results 175 for each sub-simulation can be time-series data, with corresponding results associated with each time-step of the simulation. The simulation executor 140 can execute each of the sub-simulations for all groups of virtual transducers iteratively, in parallel, or some combination thereof. Once all the simulation results 175 have been generated for all sub-simulations, the results can be combined by the results generator 145.

The results generator 145 can generate simulation results 175 for the simulation of the ultrasound procedure by combining respective results of each of the sub-simulations executed by the simulation executor 140. The results for each of the sub-simulations can be summed to generate the simulation results 175. Summing the results of each sub-simulation may be based on superposition. Summing the results of each sub-simulation may include summing data (e.g., velocity, pressure, acoustic intensity) at each point in the simulation domain for each timestep. If a sub-volume of sub-simulation did not simulate a point in the simulation domain, a value of zero can be provided for that point for that sub-simulation. In some implementations, the simulation results 175 for each sub-simulation can include a vector field of forces at each point in the corresponding sub-volume generated by the virtual transducers in the group for that sub-simulation. Points in the sub-volume may be or include voxels. However, because all sub-volumes (and therefore all simulations) included simulated results for the region of interest, the total sum of all data points within the volume of the region of interest are as accurate as if the region of interest was simulated as part of a full-field simulation for the entire simulation domain. The results can be summed for each timestep in the sub-simulations.

Once the results generator 145 has generated simulation results 175 for the region of interest, the results generator 145 can store the simulation results 175 in association with an identifier of the requested ultrasound simulation. In some implementations, the results generator 145 can transmit the simulation results 175 for the ultrasound simulation to the computing device 120 via the network. In some implementations the results generator 145 can present the simulation results 175 of the ultrasound simulation at a display device (e.g., of the data processing system 105, of the computing device 120, etc.). The results generator 145 can present one or more graphical user interfaces that enable an operator of the data processing system 105 or the computing device 120 to access, visualize, and verify all data included in the simulation results 175.

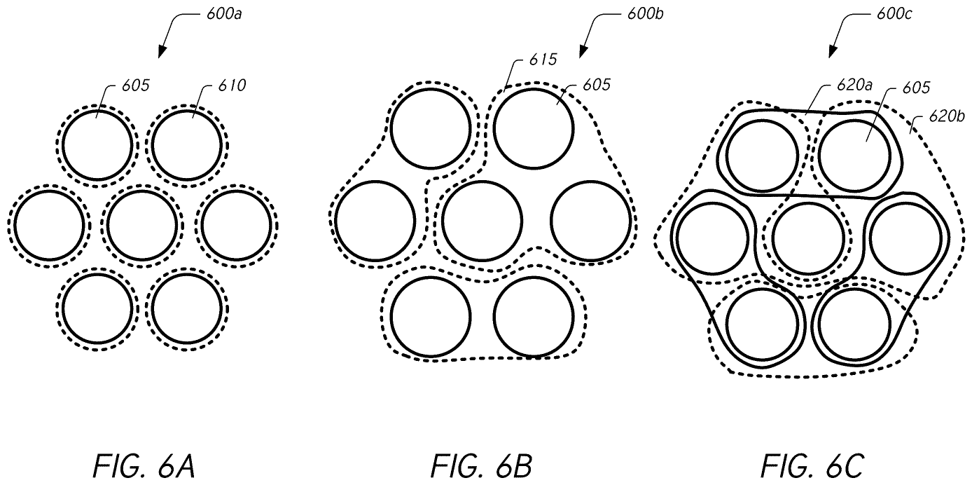

FIGS. 6A, 6B, and 6C show example diagrams 600A, 600B, and 600C illustrating how multiple transducers 605 can be simulated according to the techniques described herein. In particular, FIGS. 6A-6C illustrate examples of how transducers (or the simulation space corresponding thereto) can be grouped into subsets according to the techniques described herein. FIG. 6A illustrates an example where each transducer 605 is simulated individually. such that each transducer is separated into an individual, respective group 610. In such implementations, each transducer 605 may be simulated separately from one another as part of its respective subset 610. FIG. 6B shows an approach in which multiple transducers 605 are simulated as part of subsets 615 including multiple transducers 615. As shown, any number of transducers 605 can be included in a subset 615, for example, two transducers 605 or three transducers 605.

In some implementations, although not shown here, a subset 615 may include a single transducer while other subsets 615 may include multiple transducers. In the implementation shown in FIG. 6B, each transducer is to be simulated once as part of its respective subset 615, with each other transducer 605 that is a member of that subset 615. FIG. 6C shows an implementation in which multiple sets of transducers are simulated multiple times. For example, each of the first subsets 620A includes one or more of the same transducers as each of the first subsets 620B. Further, as shown, multiple first subsets 620A can include the same transducer 605, while not all transducers 605 may be necessarily included in one of the second subsets 620B.

In the example arrangement of FIG. 6C, each of the transducers are included in one or more first subsets 620A and at least one second subset 620B, each of which are simulated according to the techniques described herein. In such implementations, the transducers 605 can be selected for inclusion in the subsets 620A and 620B such that each transducer 605 is simulated a predetermined number of times. In this example, the transducers 605 are selected for inclusion in the subsets 620A and 620B such that each transducer 605 is simulated three times. In such implementations, when combining simulation results (e.g., via addition), the resulting simulation output can be determined by dividing the magnitude of the simulation results by the predetermined number of times each transducer 605 was simulated (in this example, by three).

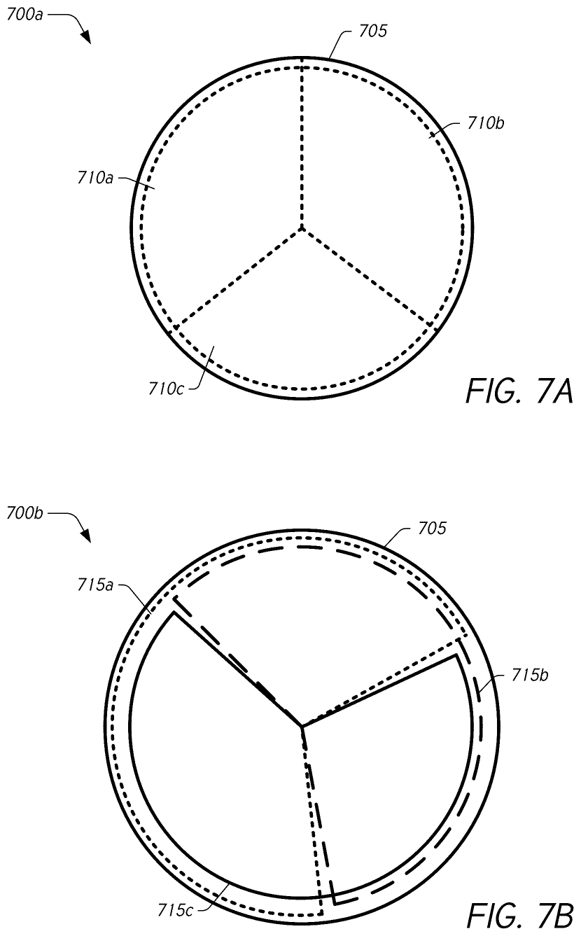

Referring to FIGS. 7A and 7B, illustrated are diagrams 700A and 700B, respectively, showing how a single transducer 705 can be sub-divided and simulated according to the techniques described herein. In addition to simulating ultrasound devices with multiple transducers, such as the transducer device shown in FIG. 2, the techniques described herein can be implemented to simulate single-transducer devices, such as the single transducer 705 shown in FIGS. 7A and 7B. In such implementations, portions of the single transducer 705 can be sub-divided and simulated according to the techniques described herein. Each subdivided portion can be simulated, and results from the simulations can be combined to generate an output simulation representing output of the entirety of the single transducer 705.

In the example implementation shown in the diagram 700A of FIG. 7A, the transducer 705 is subdivided into three regions 710A, 710B, and 710C. As shown, each of the regions 710A, 710B, and 710C of the transducer 705 are non-overlapping, and collectively represent the entirety of the transducer 705. Each of the regions 710A, 710B, and 710C of the transducer 705 can be simulated according to the techniques described herein, and the results of each simulation can be combined to produce output simulation results for the transducer 705.

In the example diagram 700B shown in FIG. 7B, multiple overlapping regions 715A, 715B, and 715C of a transducer 705 are shown. However, it should be understood that the examples shown in FIGS. 7A and 7B can include any number of sub-divided regions of the single transducer 705. In the example shown in FIG. 7B, the multiple overlapping regions 715A, 715B, and 715C of the transducer 705 are selected such that each portion of the transducer 705 is simulated a predetermined number of times (in this example, three times). Each subdivided portion can be simulated, and results from the simulations can be combined to generate an output simulation representing output of the entirety of the single transducer 705. In such implementations, when combining simulation results (e.g., via addition), the resulting simulation output can be determined by dividing the magnitude of the simulation results by the predetermined number of times each portion of the transducer 705 was simulated (in this example, by three).

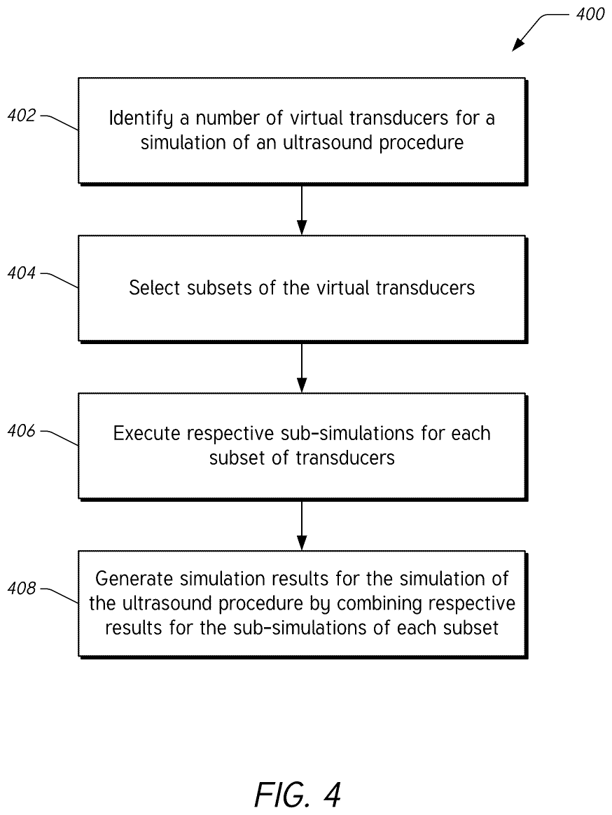

FIG. 4 is a flowchart of an example method for simulating ultrasound beam profiles, in accordance with one or more implementations. The method 400 can be executed, performed, or otherwise carried out by the data processing system 305, the computer system 500 described herein in connection with FIG. 5, or any other computing devices described herein. In brief overview, at ACT 402, the data processing system (e.g., the data processing system 105, etc.) can identify virtual transducers for a simulation of an ultrasound procedure. At ACT 404, the data processing system can select subsets (e.g., groups) of the virtual transducers. At ACT 406, the data processing system can execute simulations for the ultrasound procedure, each of the simulations corresponding respectively to a respective subset of virtual transducers. At ACT 408, the data processing system can generate simulation results for the simulation of the ultrasound procedure by combining respective results of each of the plurality of simulations.

In further detail, at ACT 402, the data processing system (e.g., the data processing system 105, etc.) can identify virtual transducers (e.g., virtual transducers 304) for a simulation of an ultrasound procedure. The data processing system can access information (e.g., settings, configuration data, etc.) relating to an ultrasound device (e.g., a virtual version of the ultrasound device 202 of FIG. 2) to be simulated. The virtual transducers (e.g., virtualized versions of the transducers 204) may be represented by data structures storing various properties of transducers of the ultrasound device, such as size, location, and beam properties (e.g., direction, actuation frequency, phase, etc.), force, an identifier of the transducer, among other properties, as described herein.

At ACT 404, the data processing system can select subsets (e.g., groups) of the virtual transducers. To do so, the data processing system may perform any of the functionality of the simulation selector 135 described in connection with FIG. 1. The data processing system can select the subsets of virtual transducers such that at least two of the subsets are overlapping with one another. In some implementations, the ultrasound procedure is a transcranial ultrasound procedure. In some implementations, the virtual transducers for the simulation are arranged in a hemispherical configuration. The virtual transducers can be selected for inclusion in groups according to their position relative to other transducers and a region of interest. In some implementations, the subsets can be selected such that the subsets of virtual transducers each share a common virtual transducer.

At ACT 406, the data processing system can execute sub-simulations for the ultrasound procedure, each of the sub-simulations corresponding respectively to a respective subset of virtual transducers. To do so, the data processing system can perform any of the functionality of the simulation executor 140 of FIG. 1. In some implementations, the data processing system can execute the sub-simulations by executing, for each sub-simulation, a time-domain acoustic simulation or a frequency-domain acoustic simulation of the respective subset corresponding to the simulation. The data processing system can identify one or more parameters of the simulation of the ultrasound procedure. The one or more parameters can include one or more of domain dimensions for the simulation, a medium type for the simulation, respective positions of each of the plurality of virtual transducers, and parameters for operating the plurality of virtual transducers. The data processing system can generate respective parameters for each of the sub-simulations based on the one or more parameters and execute each of the sub-simulations according to the respective parameters of the simulation.

At ACT 408, the data processing system can generate simulation results for the simulation of the ultrasound procedure by combining respective results of each of the plurality of simulations. To do so, the data processing system can perform any of the functionality of the results generator 145 of FIG. 1. The simulation results for the simulation of the ultrasound procedure can include a vector field of forces generated by the plurality of virtual transducers. The data processing system can transmit the simulation results to a client device (e.g., the computing device 120). In some implementations, the data processing system 105 can present the simulation results of the ultrasound procedure at a display device.

FIG. 5 illustrates a component diagram of an example computing system suitable for use in the various implementations described herein, according to an example implementation. In a non-limiting example, the computing system 500 may implement a data processing system 105 of FIG. 1, or various other example systems and devices described in the present disclosure.

The computing system 500 includes a bus 502 or other communication component for communicating information and a processor 504 coupled to the bus 502 for processing information. The computing system 500 also includes main memory 506, such as a RAM or other dynamic storage device, coupled to the bus 502 for storing information, and instructions to be executed by the processor 504. Main memory 506 may also be used for storing position information, temporary variables, or other intermediate information during execution of instructions by the processor 504. The computing system 500 may further include a ROM 508 or other static storage device coupled to the bus 502 for storing static information and instructions for the processor 504. A storage device 510, such as a solid-state device, magnetic disk, or optical disk, is coupled to the bus 502 for persistently storing information and instructions.

The computing system 500 may be coupled via the bus 502 to a display 514, such as a liquid crystal display, or active-matrix display, for displaying information to a user. An input device 512, such as a keyboard including alphanumeric and other keys, may be coupled to the bus 502 for communicating information, and command selections to the processor 504. In another implementation, the input device 512 has a touch screen display. The input device 512 may include any type of biometric sensor, or a cursor control, such as a mouse, a trackball, or cursor direction keys, for communicating direction information and command selections to the processor 504 and for controlling cursor movement on the display 514.

In some implementations, the computing system 500 may include a communications adapter 516, such as a networking adapter. Communications adapter 516 may be coupled to bus 502 and may be configured to enable communications with a computing or communications network or other computing systems. In various illustrative implementations, any type of networking configuration may be achieved using communications adapter 516, such as wired (e.g., via Ethernet), wireless (e.g., via Wi-Fi, Bluetooth), satellite (e.g., via GPS) pre-configured, ad-hoc, LAN, WAN, and the like.

According to various implementations, the processes of the illustrative implementations that are described herein may be achieved by the computing system 500 in response to the processor 504 executing an implementation of instructions contained in main memory 506. Such instructions may be read into main memory 506 from another computer-readable medium, such as the storage device 510. Execution of the implementation of instructions contained in main memory 506 causes the computing system 500 to perform the illustrative processes described herein. One or more processors in a multi-processing implementation may also be employed to execute the instructions contained in main memory 506. In alternative implementations, hard-wired circuitry may be used in place of or in combination with software instructions to implement illustrative implementations. Thus, implementations are not limited to any specific combination of hardware circuitry and software.

The implementations described herein have been described with reference to drawings. The drawings illustrate certain details of specific implementations that implement the systems, methods, and programs described herein. Describing the implementations with drawings should not be construed as imposing on the disclosure any limitations that may be present in the drawings.

It should be understood that no claim element herein is to be construed under the provisions of 35 U.S.C. § 112(f) unless the element is expressly recited using the phrase “means for.”

As used herein, the term “circuit” may include hardware structured to execute the functions described herein. In some implementations, each respective “circuit” may include machine-readable media for configuring the hardware to execute the functions described herein. The circuit may be embodied as one or more circuitry components including, but not limited to, processing circuitry, network interfaces, peripheral devices, input devices, output devices, sensors, etc. In some implementations, a circuit may take the form of one or more analog circuits, electronic circuits (e.g., integrated circuits (IC), discrete circuits, system on a chip (SOC) circuits), telecommunication circuits, hybrid circuits, and any other type of “circuit.” In this regard, the “circuit” may include any type of component for accomplishing or facilitating achievement of the operations described herein. In a non-limiting example, a circuit as described herein may include one or more transistors, logic gates (e.g., NAND, AND, NOR, OR, XOR, NOT, XNOR), resistors, multiplexers, registers, capacitors, inductors, diodes, wiring, and so on.

The “circuit” may also include one or more processors communicatively coupled to one or more memory or memory devices. In this regard, the one or more processors may execute instructions stored in the memory or may execute instructions otherwise accessible to the one or more processors. In some implementations, the one or more processors may be embodied in various ways. The one or more processors may be constructed in a manner sufficient to perform at least the operations described herein. In some implementations, the one or more processors may be shared by multiple circuits (e.g., circuit A and circuit B may comprise or otherwise share the same processor, which, in some example implementations, may execute instructions stored, or otherwise accessed, via different areas of memory). Additionally or alternatively, the one or more processors may be structured to perform or otherwise execute certain operations independent of one or more co-processors.

In other example implementations, two or more processors may be coupled via a bus to enable independent, parallel, pipelined, or multi-threaded instruction execution. Each processor may be implemented as one or more general-purpose processors, ASICs, FPGAs, GPUs, TPUs, digital signal processors (DSPs), or other suitable electronic data processing components structured to execute instructions provided by memory. The one or more processors may take the form of a single core processor, multi-core processor (e.g., a dual core processor, triple core processor, or quad core processor), microprocessor, etc. In some implementations, the one or more processors may be external to the apparatus, in a non-limiting example, the one or more processors may be a remote processor (e.g., a cloud-based processor). Alternatively or additionally, the one or more processors may be internal or local to the apparatus. In this regard, a given circuit or components thereof may be disposed locally (e.g., as part of a local server, a local computing system) or remotely (e.g., as part of a remote server such as a cloud-based server). To that end, a “circuit” as described herein may include components that are distributed across one or more locations.

An exemplary system for implementing the overall system or portions of the implementations might include a general-purpose computing device in the form of computers, including a processing unit, a system memory, and a system bus that couples various system components including the system memory to the processing unit. Each memory device may include non-transient volatile storage media, non-volatile storage media, non-transitory storage media (e.g., one or more volatile or non-volatile memories), etc. In some implementations, the non-volatile media may take the form of ROM, flash memory (e.g., flash memory such as NAND, 3D NAND, NOR, 3D NOR), EEPROM, MRAM, magnetic storage, hard discs, optical discs, etc. In other implementations, the volatile storage media may take the form of RAM, TRAM, ZRAM, etc. Combinations of the above are also included within the scope of machine-readable media. In this regard, machine-executable instructions comprise, in a non-limiting example, instructions and data, which cause a general-purpose computer, special purpose computer, or special purpose processing machines to perform a certain function or group of functions. Each respective memory device may be operable to maintain or otherwise store information relating to the operations performed by one or more associated circuits, including processor instructions and related data (e.g., database components, object code components, script components), in accordance with the example implementations described herein.

It should also be noted that the term “input devices,” as described herein, may include any type of input device including, but not limited to, a keyboard, a keypad, a mouse, joystick, or other input devices performing a similar function. Comparatively, the term “output device,” as described herein, may include any type of output device including, but not limited to, a computer monitor, printer, facsimile machine, or other output devices performing a similar function.

It should be noted that although the diagrams herein may show a specific order and composition of method steps, it is understood that the order of these steps may differ from what is depicted. In a non-limiting example, two or more steps may be performed concurrently or with partial concurrence. Also, some method steps that are performed as discrete steps may be combined, steps being performed as a combined step may be separated into discrete steps, the sequence of certain processes may be reversed or otherwise varied, and the nature or number of discrete processes may be altered or varied. The order or sequence of any element or apparatus may be varied or substituted according to alternative implementations. Accordingly, all such modifications are intended to be included within the scope of the present disclosure as defined in the appended claims. Such variations will depend on the machine-readable media and hardware systems chosen and on designer choice. It is understood that all such variations are within the scope of the disclosure. Likewise, software and web implementations of the present disclosure could be accomplished with standard programming techniques with rule-based logic and other logic to accomplish the various database searching steps, correlation steps, comparison steps, and decision steps.

While this specification contains many specific implementation details, these should not be construed as limitations on the scope of any inventions or of what may be claimed, but rather as descriptions of features specific to particular implementations of the systems and methods described herein. Certain features that are described in this specification in the context of separate implementations may also be implemented in combination in a single implementation. Conversely, various features that are described in the context of a single implementation may also be implemented in multiple implementations separately or in any suitable subcombination. Moreover, although features may be described above as acting in certain combinations and even initially claimed as such, one or more features from a claimed combination may in some cases be excised from the combination, and the claimed combination may be directed to a subcombination or variation of a subcombination.

In certain circumstances, multitasking and parallel processing may be advantageous. Moreover, the separation of various system components in the implementations described above should not be understood as requiring such separation in all implementations, and it should be understood that the described program components and systems may generally be integrated together in a single software product or packaged into multiple software products.

Having now described some illustrative implementations and implementations, it is apparent that the foregoing is illustrative and not limiting, having been presented by way of example. In particular, although many of the examples presented herein involve specific combinations of method acts or system elements, those acts and those elements may be combined in other ways to accomplish the same objectives. Acts, elements, and features discussed only in connection with one implementation are not intended to be excluded from a similar role in other implementations.

The phraseology and terminology used herein is for the purpose of description and should not be regarded as limiting. The use of “including,” “comprising,” “having,” “containing,” “involving,” “characterized by,” “characterized in that,” and variations thereof herein, is meant to encompass the items listed thereafter, equivalents thereof, and additional items, as well as alternate implementations consisting of the items listed thereafter exclusively. In one implementation, the systems and methods described herein consist of one, each combination of more than one, or all of the described elements, acts, or components.

Any references to implementations or elements or acts of the systems and methods herein referred to in the singular may also embrace implementations including a plurality of these elements, and any references in plural to any implementation or element or act herein may also embrace implementations including only a single element. References in the singular or plural form are not intended to limit the presently disclosed systems or methods, their components, acts, or elements to single or plural configurations. References to any act or element being based on any information, act, or element may include implementations where the act or element is based at least in part on any information, act, or element.

Any implementation disclosed herein may be combined with any other implementation, and references to “an implementation,” “some implementations,” “an alternate implementation,” “various implementation,” “one implementation,” or the like are not necessarily mutually exclusive and are intended to indicate that a particular feature, structure, or characteristic described in connection with the implementation may be included in at least one implementation. Such terms as used herein are not necessarily all referring to the same implementation. Any implementation may be combined with any other implementation, inclusively or exclusively, in any manner consistent with the aspects and implementations disclosed herein.

References to “or” may be construed as inclusive so that any terms described using “or” may indicate any of a single, more than one, and all of the described terms.

Where technical features in the drawings, detailed description or any claim are followed by reference signs, the reference signs have been included for the sole purpose of increasing the intelligibility of the drawings, detailed description, and claims. Accordingly, neither the reference signs nor their absence have any limiting effect on the scope of any claim elements.

The foregoing description of implementations has been presented for purposes of illustration and description. It is not intended to be exhaustive or to limit the disclosure to the precise form disclosed, and modifications and variations are possible in light of the above teachings or may be acquired from this disclosure. The implementations were chosen and described in order to explain the principals of the disclosure and its practical application to enable one skilled in the art to utilize the various implementations and with various modifications as are suited to the particular use contemplated. Other substitutions, modifications, changes, and omissions may be made in the design, operating conditions and implementation of the implementations without departing from the scope of the present disclosure as expressed in the appended claims.

### Additional Embodiments and Terminology

The present disclosure describes various features, no single one of which is solely responsible for the benefits described herein. It will be understood that various features described herein may be combined, modified, or omitted, as would be apparent to one of ordinary skill. Other combinations and sub-combinations than those specifically described herein will be apparent to one of ordinary skill and are intended to form a part of this disclosure. Various methods are described herein in connection with various flowchart steps and/or phases. It will be understood that in many cases, certain steps and/or phases may be combined together such that multiple steps and/or phases shown in the flowcharts can be performed as a single step and/or phase. Also, certain steps and/or phases can be broken into additional sub-components to be performed separately. In some instances, the order of the steps and/or phases can be rearranged, and certain steps and/or phases may be omitted entirely. Also, the methods described herein are to be understood to be open-ended, such that additional steps and/or phases to those shown and described herein can also be performed.

Some aspects of the systems and methods described herein can advantageously be implemented using, for example, computer software, hardware, firmware, or any combination of computer software, hardware, and firmware. Computer software can comprise computer executable code stored in a computer readable medium (e.g., non-transitory computer readable medium) that, when executed, performs the functions described herein. In some embodiments, computer-executable code is executed by one or more general purpose computer processors. A skilled artisan will appreciate, in light of this disclosure, that any feature or function that can be implemented using software to be executed on a general-purpose computer can also be implemented using a different combination of hardware, software, or firmware. For example, such a module can be implemented completely in hardware using a combination of integrated circuits. Alternatively or additionally, such a feature or function can be implemented completely or partially using specialized computers designed to perform the particular functions described herein rather than by general purpose computers.

Multiple distributed computing devices can be substituted for any one computing device described herein. In such distributed embodiments, the functions of the one computing device are distributed (e.g., over a network) such that some functions are performed on each of the distributed computing devices.

Some embodiments may be described with reference to equations, algorithms, and/or flowchart illustrations. These methods may be implemented using computer program instructions executable on one or more computers. These methods may also be implemented as computer program products either separately, or as a component of an apparatus or system. In this regard, each equation, algorithm, block, or step of a flowchart, and combinations thereof, may be implemented by hardware, firmware, and/or software including one or more computer program instructions embodied in computer-readable program code logic. As will be appreciated, any such computer program instructions may be loaded onto one or more computers, including without limitation a general purpose computer or special purpose computer, or other programmable processing apparatus to produce a machine, such that the computer program instructions which execute on the computer(s) or other programmable processing device(s) implement the functions specified in the equations, algorithms, and/or flowcharts. It will also be understood that each equation, algorithm, and/or block in flowchart illustrations, and combinations thereof, may be implemented by special purpose hardware-based computer systems which perform the specified functions or steps, or combinations of special purpose hardware and computer-readable program code logic means.

Furthermore, computer program instructions, such as embodied in computer-readable program code logic, may also be stored in a computer readable memory (e.g., a non-transitory computer readable medium) that can direct one or more computers or other programmable processing devices to function in a particular manner, such that the instructions stored in the computer-readable memory implement the function(s) specified in the block(s) of the flowchart(s). The computer program instructions may also be loaded onto one or more computers or other programmable computing devices to cause a series of operational steps to be performed on the one or more computers or other programmable computing devices to produce a computer-implemented process such that the instructions which execute on the computer or other programmable processing apparatus provide steps for implementing the functions specified in the equation(s), algorithm(s), and/or block(s) of the flowchart(s).

Some or all of the methods and tasks described herein may be performed and fully automated by a computer system. The computer system may, in some cases, include multiple distinct computers or computing devices (e.g., physical servers, workstations, storage arrays, etc.) that communicate and interoperate over a network to perform the functions described. Each such computing device typically includes a processor (or multiple processors) that executes program instructions or modules stored in a memory or other non-transitory computer-readable storage medium or device. The various functions disclosed herein may be embodied in such program instructions, although some or all of the disclosed functions may alternatively be implemented in application-specific circuitry (e.g., ASICs or FPGAs) of the computer system. Where the computer system includes multiple computing devices, these devices may, but need not, be co-located. The results of the disclosed methods and tasks may be persistently stored by transforming physical storage devices, such as solid-state memory chips and/or magnetic disks, into a different state.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list. The word “exemplary” is used exclusively herein to mean “serving as an example, instance, or illustration.” Any implementation described herein as “exemplary” is not necessarily to be construed as preferred or advantageous over other implementations.

The disclosure is not intended to be limited to the implementations shown herein. Various modifications to the implementations described in this disclosure may be readily apparent to those skilled in the art, and the generic principles defined herein may be applied to other implementations without departing from the spirit or scope of this disclosure. The teachings of the invention provided herein can be applied to other methods and systems and are not limited to the methods and systems described above, and elements and acts of the various embodiments described above can be combined to provide further embodiments. Accordingly, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

What is claimed is:

1. A method, comprising:
identifying, by one or more processors coupled to non-transitory memory, a plurality of virtual transducers for a simulation of an ultrasound procedure;
selecting, by the one or more processors, a plurality of subsets of the plurality of virtual transducers;
executing, by the one or more processors, a plurality of simulations for the ultrasound procedure, each of the plurality of simulations corresponding respectively to a respective subset of the plurality of subsets; and
generating, by the one or more processors, simulation results for the simulation of the ultrasound procedure by combining respective results of each of the plurality of simulations.

2. The method of claim 1, further comprising selecting, by the one or more processors, the plurality of subsets such that at least two of the plurality of subsets are overlapping with one another.

3. The method of claim 1, wherein the plurality of subsets each share a common simulation volume.

4. The method of claim 1, wherein executing the plurality of simulations comprises executing, by the one or more processors, for each of the plurality of simulations, a time-domain acoustic simulation of the respective subset or a frequency-domain acoustic simulation of the respective subset.

5. The method of claim 1, further comprising:
identifying, by the one or more processors, one or more parameters of the simulation of the ultrasound procedure, the one or more parameters comprising one or more of a number of dimensions for the simulation, a medium type for the simulation, respective positions of each of the plurality of virtual transducers, and parameters for operating the plurality of virtual transducers; and
executing, by the one or more processors, the plurality of simulations according to the one or more parameters.

6. The method of claim 5, further comprising:
generating, by the one or more processors, respective parameters for each of the plurality of simulations based on the one or more parameters; and
executing, by the one or more processors, each of the plurality of simulations according to the respective parameters of the simulation.

7. The method of claim 1, wherein selecting the plurality of subsets is further based on a target region defined in the simulation of the ultrasound procedure.

8. The method of claim 1, wherein the simulation results for the simulation of the ultrasound procedure comprises a field of forces generated by the plurality of virtual transducers.

9. The method of claim 1, further comprising presenting, by the one or more processors, the simulation results of the ultrasound procedure at a display device.

10. The method of claim 1, wherein executing the plurality of simulations comprises independently executing each simulation of the plurality of simulations prior to combining the respective results of each simulation of the plurality of simulations.

11. A system, comprising:
one or more processors coupled to non-transitory memory, the one or more processors configured to:
identify a plurality of virtual transducers for a simulation of an ultrasound procedure;
select a plurality of subsets of the plurality of virtual transducers;
execute a plurality of simulations for the ultrasound procedure, each of the plurality of simulations corresponding respectively to a respective subset of the plurality of subsets; and
generate simulation results for the simulation of the ultrasound procedure by combining respective results of each of the plurality of simulations.

12. The system of claim 11, wherein the one or more processors are further configured to select the plurality of subsets such that at least two of the plurality of subsets overlap with one another.

13. The system of claim 11, wherein the plurality of subsets each share a simulation volume.

14. The system of claim 11, wherein the one or more processors are further configured to execute the plurality of simulations by executing, for each of the plurality of simulations, a time-domain acoustic simulation of the respective subset or a frequency-domain acoustic simulation of the respective subset.

15. The system of claim 11, wherein the one or more processors are further configured to:
identify one or more parameters of the simulation of the ultrasound procedure, the one or more parameters comprising one or more of a number of dimensions for the simulation, a medium type for the simulation, respective positions of each of the plurality of virtual transducers, and parameters for operating the plurality of virtual transducers; and
execute the plurality of simulations according to the one or more parameters.

16. The system of claim 15, wherein the one or more processors are further configured to:
generate respective parameters for each of the plurality of simulations based on the one or more parameters; and
execute each of the plurality of simulations according to the respective parameters of the simulation.

17. The system of claim 11, wherein the simulation results for the simulation of the ultrasound procedure comprises a field of forces generated by the plurality of virtual transducers.

18. The system of claim 11, wherein the one or more processors are further configured to present the simulation results of the ultrasound procedure at a display device.

19. The system of claim 11, wherein:
the ultrasound procedure is a transcranial ultrasound procedure, and
the plurality of virtual transducers for the simulation are arranged in a hemispherical configuration.

20. A system, comprising:
one or more processors coupled to non-transitory memory, the one or more processors configured to:
identify a plurality of portions of a virtual transducer for a simulation of an ultrasound procedure;
execute a plurality of simulations for the ultrasound procedure, each of the plurality of simulations corresponding respectively to at least one portion of the plurality of portions of the virtual transducer; and
generate a simulation result for the simulation of the ultrasound procedure by combining respective results of each of the plurality of simulations.
